(19) United States
(12) Patent Application Publication
(10) Pub. No.: US 2025/0208167 A1
(43) Pub. Date: Jun. 26, 2025

(54) TEST INSTRUMENT AND TEST LEAD EXTENSION FOR ONE HANDED TESTING OF AN ELECTRICAL DEVICE

(71) Applicant: John Riccitelli, San Jose, CA (US)

(72) Inventor: John Riccitelli, San Jose, CA (US)

(21) Appl. No.: 18/898,423

(22) Filed: Sep. 26, 2024

Related U.S. Application Data
(60) Provisional application No. 63/614,315, filed on Dec. 22, 2023.

(51) Int. Cl. G01R 1/067; G01R 31/28

(52) U.S. Cl. CPC G01R 1/06788; G01R 31/2889

(57) ABSTRACT

In one example, a test instrument comprises a handheld testing device having pivoting first and second jaws to pivot from a first open position with a spacing between the distal ends of the first and second jaws and a second closed position with no spacing between the distal ends of the first and second jaws. A first test leads holder is attached to the first jaw and has an opening to hold a first test lead. A second test leads holder is attached to the second jaw and has an opening to hold a second test lead. A pivot pivotally couples the first jaws and the second jaws to allow a user to adjust a spacing between the first test lead and the second test lead with one hand to test voltage of an electrical device without having electrical current accidentally go through a body of the user.

### CROSS-REFERENCE TO RELATED APPLICATION

This application claims the benefit of U.S. Provisional Application No. 63/614,315, filed on Dec. 22, 2023 entitled: “One Handed Test Leads Holder”, the contents of which are incorporated by reference herein.

### FIELD

Embodiments of the present disclosure relate to electrical test tools including a one handed test leads holder tool and a test leads holder of a test instrument for one handed testing of an electrical device.

### BACKGROUND

Voltmeters and multi-meters are commonly used to check the amount of voltage, resistance, or continuity between two points. Generally, a voltmeter or multimeter has two test leads each connected to the voltmeter or multimeter with wires. To check for voltage or make an electrical test an operator (e.g., an electrician, user) needs to touch each test lead to the different points on the equipment being tested. The operator can then look at the voltmeter or multimeter and determine the voltage or other readings present between the two points.

The danger occurs when an operator needs to use such a voltmeter or multimeter to check voltages above 40 volts or so, which is very common in most electrical work. Most structural wiring is between 110 and 240 volts, which is enough voltage and current to cause serious injury or death. It is also very common to perform electrical tests using common voltage/multimeters on structural wiring from 240 on up to 600 volts, and much higher in some cases. It is potentially dangerous to hold a lead in each hand and perform a test, and so users are advised to hold both test leads with one hand, and yet is very difficult to hold both leads in one hand especially when the test points are often spaced some distance away from one another. This is further complicated if the operator doing the testing needs to also hold the voltage meter itself in one of their hands also.

### SUMMARY

The present disclosure allows an operator to hold the two separate test leads and a test instrument itself with one hand, while performing electrical test operations of an electrical device. The operator simply attaches a test leads holding tool to their test instrument (e.g. voltmeter, multi-meter, ammeter, etc.) and attaches the test leads to each arm of the test leads holding tool. In one example, one handed test leads holder tool includes a first elongated member having a first non-metallic clip at a distal end to hold a first test lead, a second elongated member having an extendable or removable segment and a second non-metallic clip at a distal end to hold a second test lead, and a pivot to pivotally couple the first elongated member to the second elongated member. This allows a user to position the first test lead and the second test lead using a lever or finger trigger of the tool to control the motion of the first and second elongated members to test electrical parameters of an electrical device to avoid the risk of electrical current accidentally entering or passing through a body of the user.

In another embodiment, a test instrument comprises a handheld testing device having pivoting first and second jaws to pivot from a first open position with a spacing between the distal ends of the first and second jaws and a second closed position with no spacing between the distal ends of the first and second jaws. A first test leads holder is attached to the first jaw and has an opening to hold a first test lead. A second test leads holder is attached to the second jaw and has an opening to hold a second test lead. A pivot pivotally couples the first jaws and the second jaws to allow a user to adjust a spacing between the first test lead and the second test lead with one hand to test voltage of an electrical device without having electrical current accidentally go through a body of the user.

Other embodiments comprise the adaption of an attachment point for a test leads holder to the moveable arm of a typical ammeter or clamp on meter. Thus, the test leads motion can be controlled with the lever or finger trigger of the ammeter. Other embodiments are also described. Other features of embodiments of the present disclosure will be apparent from the accompanying drawings and from the detailed description which follows.

### BRIEF DESCRIPTION OF THE DRAWINGS

The embodiments of the present disclosure are illustrated by way of example and not by way of limitation in the figures of the accompanying drawings in which like references indicate similar elements. It should be noted that references to “an” or “one” embodiment of the present disclosure in this disclosure are not necessarily to the same embodiment, and they mean at least one.

Following is a brief description of the drawing with reference numbers:

FIG. 1A illustrates a detailed front view drawing of a ‘one handed voltage meter and test leads holder tool 100’ (hereinafter is referred to only as ‘test leads holder’ or ‘test leads holder tool’) in accordance with one embodiment.

FIG. 1B illustrates a side view of a test leads holder tool and a side view of an adapter/holder to hold a test instrument (e.g., voltmeter/multi-meter, ammeter, etc.).

FIG. 2 illustrates a front view showing a tool B-126 having removable flexible arms 128 including a short flexible extension arm in accordance with one embodiment.

FIGS. 3A and 3B illustrate a method C-138 of attaching a test instrument to a test leads holder in accordance with one embodiment.

FIG. 4 illustrates a front view of an ammeter having a test leads holder attached to the front in accordance with one embodiment.

FIG. 5 illustrates a front view of an ammeter having a test leads holder attached to the side with jaws in a closed position in accordance with one embodiment.

FIG. 6 illustrates a back view of an ammeter having a test leads holder attached to the side with jaws in a closed position in accordance with one embodiment.

FIG. 7 illustrates an ammeter having a test leads holder attached to the side with jaws in an open position in accordance with one embodiment.

FIG. 8 illustrates an ammeter having a test leads holder attached to the side with jaws in an open position in accordance with one embodiment.

FIG. 9 illustrates an ammeter having a test leads holder attached to the back with jaws in a closed position in accordance with one embodiment.

FIG. 10 illustrates an ammeter having a test leads holder attached to the back with jaws in a closed position in accordance with one embodiment.

FIG. 11 illustrates an ammeter having a test leads holder attached to the back with jaws in an open position in accordance with one embodiment.

FIG. 12 illustrates an ammeter having a test leads holder attached to the back with jaws in an open position in accordance with one embodiment.

FIG. 13 illustrates an ammeter having a test leads holder attached to the back with jaws in an open position with longer accessory test leads attached in accordance with one embodiment.

FIG. 14 illustrates an ammeter having a test leads holder with jaws in an open position and test leads extensions in accordance with one embodiment.

FIG. 15 illustrates an ammeter having a test leads holder with jaws in an open position and flexible test leads extensions in accordance with one embodiment.

FIG. 16 illustrates an ammeter having a test leads holder with jaws in an open position and telescoping test leads extensions in accordance with one embodiment.

FIG. 17 illustrates an ammeter having a test leads holder attached to the side with jaws in an open position and flexible test leads being connected to electrical lines in an electrical panel in accordance with one embodiment.

### DETAILED DESCRIPTION

All references cited herein are incorporated herein in their entireties. If there is a conflict between a definition herein and in an incorporated reference, the definition herein shall control. At least one of A, B, and C refers to a selection of A alone, B alone, C alone, a combination of A and B, a combination of A and C, a combination of B and C, or a combination of A and B and C.

### Definitions

Voltage: Voltage, also known as potential difference, electric pressure, or electric tension is the difference in electric potential between two points. In a static electric field, it corresponds to the work needed per unit of charge to move a positive test charge from the first point to the second point. Voltage is the electric pressure from an electrical circuit's power source that pushes charged electrons (current) through a conductor, enabling the electrons to do work such as illuminating a light. In brief, voltage=pressure, and it is measured in volts.

Electrical Safety: Recognizing hazards associated with the use of electrical energy and taking precautions so that hazards do not cause injury or death. Voltage testing is a common procedure when working with electricity, yet electric voltage and current can be very dangerous and fatal if precautions are not followed. A common rule in electrical voltage tests with meters is to use only one hand to hold both test leads, as voltage and current are most dangerous when they pass through the arms from one arm to the other as the electricity naturally tries to find a path of least resistance which is generally the other end of the two test points. When holding one test lead in each hand the users body becomes the shortest path to the other test lead if the wires are faulty in any way or if the users hand touches a live test point. The greatest danger is that during an electrical test the electricity could pass through the users heart while going from one arm to the other arm resulting in electrocution or ventricular fibrillation of heart. When current flows through the human body, it can cause a lot of problems. Currents as low as 10 mA can cause severe muscle contractions and burns, while currents of 20 mA or greater can cause paralysis of the muscles that allow you to breathe. If a current from outside the body passes through the heart, it can mask these impulses and disturb the heart's rhythm. This irregular heartbeat is called arrhythmia and can even manifest as a total disorganization of the rhythm, known as ventricular fibrillation.

Voltage testing: Voltage is needed to operate most any electrical circuit or device and so it is a very common test when checking electrical and or electronic equipment. Voltage testing is an essential procedure that should be completed before carrying out any work on an electrical installation. Ensuring the absence of voltage can be vital for safety reasons and the main purpose is to limit the risks that live electrical circuits and equipment can pose to individuals.

Multimeter definitions: The most common handheld electrical test instruments are voltmeters, multimeters, and ammeters. Handheld ammeters, are most commonly called ‘clamp on meters’ or just ‘clamp meters’ because the jaws open and close to go around electrical cables. Voltmeters are most commonly called multimeters as most are digital rather than analog, and they have ‘multiple’ functions. Analog meters are still common but just not as popular with professionals who need multiple test functions, and or a variety of electrical tests to perform. Analog and digital meters are generally similar in shape and design, and both are used in the same way to do electrical tests, so a one handed leads holder would work with either meter and would benefit the user of either meter.

Voltmeter meter/Voltage meter: An instrument for measuring electric potential in volts. Typically, the voltmeter has a digital or analog screen to see and read the value in volts. Typically, the voltmeter or voltage meter has two test leads which are attached to the meter with wires. The wires are generally two to three feet in length and have metal tips on the ends of the test leads to make contact with a test point. The test leads are generally plugged into various ports on the meter depending on what type of test is being conducted. Generally, if not always, only two wires are needed to do a voltage test with a meter.

Multimeter: An instrument designed to measure electric current, voltage, and usually resistance, typically over several ranges of value.

Ammeter: An instrument for measuring electric current in amperes. Typically, the ammeter has a digital or analog screen to display the measured values in amperes.

Clamp on ammeter/clamp meter: is a clothespin-shaped instrument that can be clamped around a live wire in order to measure the current being carried by the live wire. As a measurement principle, clamp meters detect the magnetic field emitted by current flowing in a wire in order to measure the current value. The clamp meters generally have nonmetallic jaws that open so that the clamp meters can be put onto a piece of wire without disconnecting the wire, and the amperage is then displayed on the screen of the ammeter when it is set to read amperes.

Test lead: An insulated wire that connects a test instrument, such as a voltmeter, multimeter, ammeter or an oscilloscope, to the device under test (DUT). Test leads are typically used to measure voltage, current, and resistance, among other electrical characteristics Test instruments and test leads are a temporary connection to electrical systems, often live at the time, for the purpose of making measurements to establish or confirm various parameters of electrical equipment.

### REFERENCE NUMBERS FOR DRAWINGS 1-17

100—Detailed drawing of ‘one handed voltage meter and test leads holder’
102—Non-metallic clips to hold test leads.
104—Flexible arm.
106—Stationary arm.
108—Extendable arm/removable arm tightening nut.
110—Extendable arm sleeve.
112—Pivot stud.
114—Spring.
116—Voltmeter/multi-meter adapter/holder.
118—Adapter holes for bolts.
120—Adapter bolts, washers and nuts.
122—Adapter spacer.
124—Hand grips.
126—Front views showing removable flexible arms and adapter.
128—Short flexible extension arm.
130—Optional longer flexible extension arm.
132—Adapter/holder for voltmeter/multi-meter.
134—Bolt holes for attaching test leads holder to adapter.
136—Squeezing hand grips together moves test leads together.
138—Drawing: showing the three steps of attaching pieces together.
140—Step one: Attach the two test leads onto the arms of test leads holder.
142—Step two: Attach leads holder to voltmeter/multi-meter adapter/holder.
144—Step three: Attach voltmeter/multi-meter to adapter/holder.
146—Test leads holder and voltmeter/multi-meter all as one unit.
000—Typical Ammeter jaws in the closed position.
002—Typical test lead.
004—Test lead holder (invention) attached or molded onto the ‘front’ of the opening jaw of a typical Ammeter.
006—Typical button trigger for opening a typical Ammeters jaw.
008—Stationary Ammeter jaw.
010—Typical test lead holder on the stationary side of an Ammeters jaw.
012—Front side of typical Ammeter. Typical of what most all Ammeters look like that have multimeter and voltage meters functions.
014—Back side of typical Ammeter.
016—Typical Ammeter jaw in the open position.
018—Test lead holder (invention) attached or molded onto the ‘side’ of the opening jaw of a typical Ammeter.
020—Test lead holder (invention) attached or molded onto the ‘back’ of the opening jaw of a typical Ammeter.
022—Accessory: Longer test leads.
024A—Accessory: Lower portion of flexible test lead extensions.
024B—Accessory: Flexible upper portion of test lead extensions.
026—Accessory: Flexible test lead adapter boot.
028—Showing: Attaching accessory test lead adapter.
030—Showing: Telescoping/extendable portion of accessory test leads.
032—Accessory telescoping/extendable test lead adapter.
034—Demonstration of common test points during a voltage test.
036—Showing: Ammeter being used in one handed operation.
038—Showing: movement of typical ammeter jaws.

### Technical Solution

This present disclosure allows a person to hold two separate test leads and an electrical test instrument (e.g., voltmeter, multimeter, ammeter) with one hand, while performing electrical test operations. The user simply attaches this novel test leads holding tool to their voltmeter/multi-meter and attaches the test leads to each arm of the test leads holder tool.

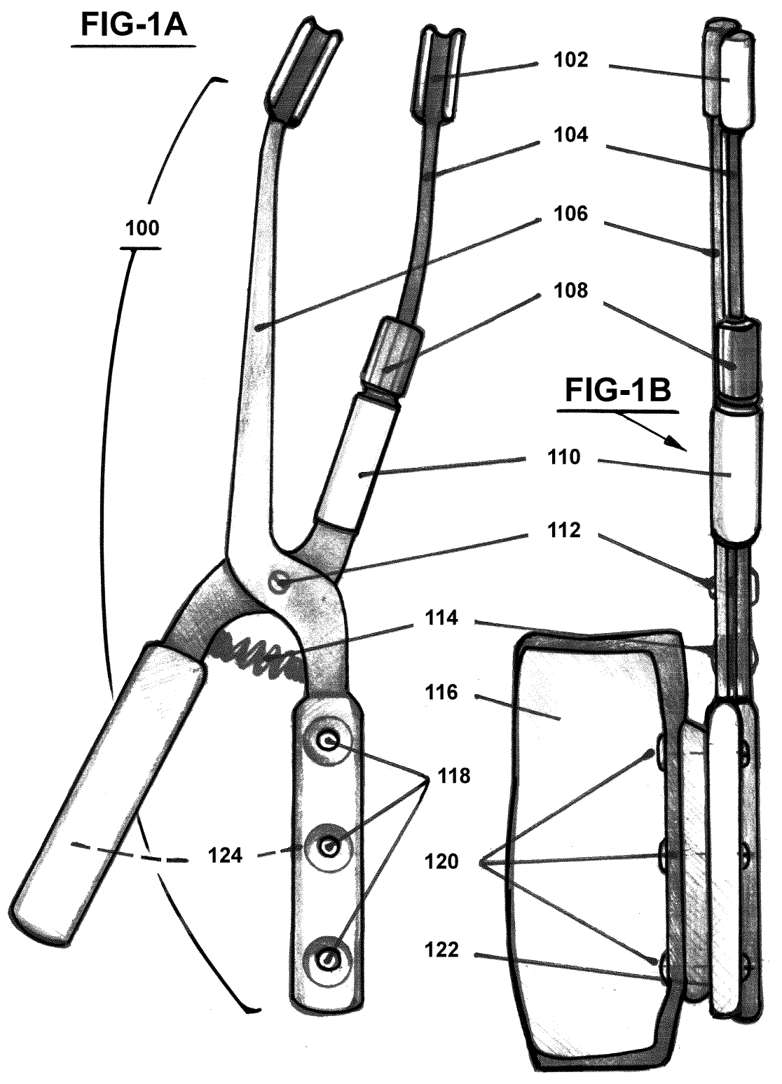

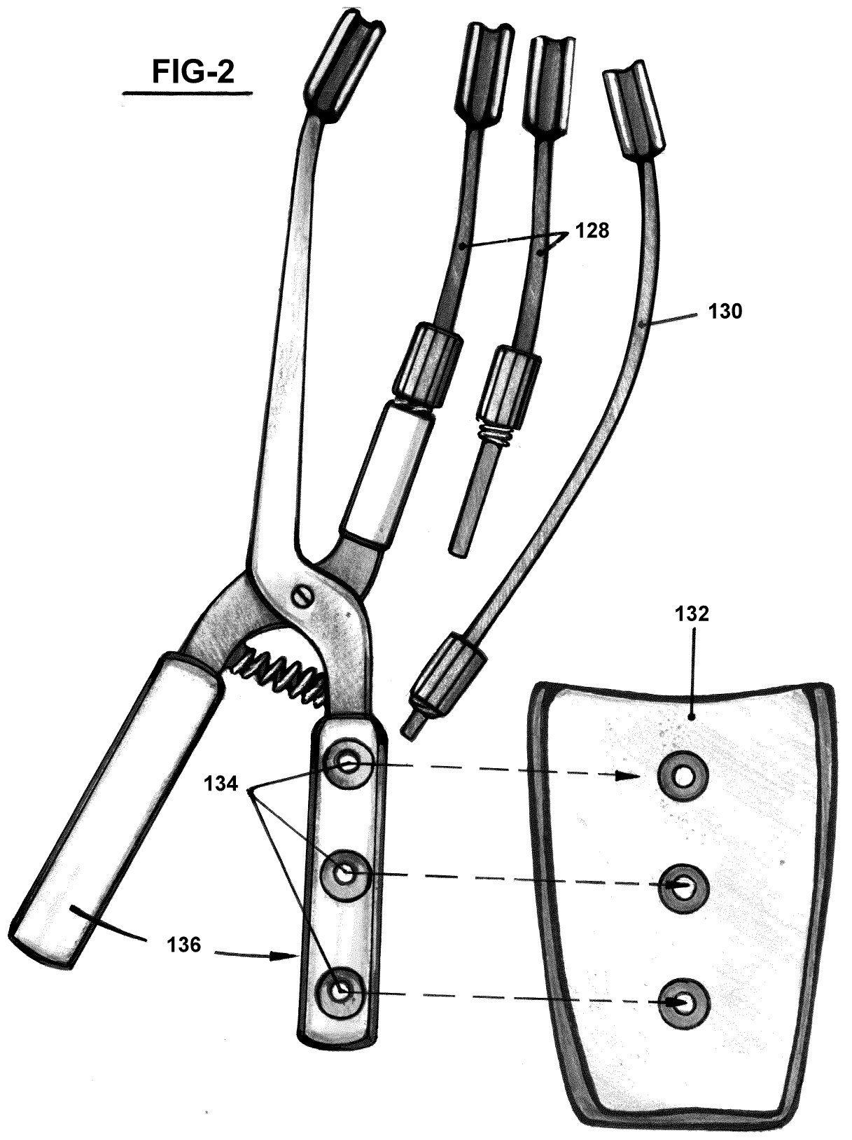

A one handed test leads holder tool connects to a test instrument. In one example, the shape of this tool is similar to a pair of scissors, pliers, or wire strippers. The one handed test leads holder tool opens and closes with a squeeze of the handles as illustrated in FIGS. 1A and 1B. The handles are connected with a pivot screw 112 and tension is provided by a biasing mechanism 114 (e.g., spring 114).

FIG. 1A illustrates a detailed drawing of a ‘one handed voltage meter and test leads holder tool 100 (hereinafter is referred to only as ‘test leads holder’ or ‘test leads holder tool’) in accordance with one embodiment. The test leads holder tool 100 includes non-metallic clips 102 to hold test leads. The tool 100 includes a flexible arm 104 (e.g., elongated member), a stationary arm 106 (e.g., elongated member), an extendable arm/removable arm 108 (e.g., elongated member) with a tightening nut 108, an extendable arm sleeve 110, a pivot stud 112, and a biasing mechanism 114.

A voltmeter/multi-meter adapter/holder 116 as shown in FIG. 1B functions to hold a test instrument (e.g., voltmeter/multi-meter). The tool 100 also includes adapter holes 118 for using adapter bolts, washers and nuts 120 for attaching the tool 100 to the holder 116 to form a one handed test apparatus as illustrated in FIG. 1B. An adapter spacer 122 provides a spacing between the adapter/holder 116 and the tool 100. Hand grips 124 provide a user with a more comfortable fatigue reducing surface to grip the tool 100.

The one handed test leads holder tool can be shaped like scissors with a flexible clip to hold the test leads. The test leads are held by the tension of the flexible clips on the ends of the tools two arms 102. The leads open wider with a squeeze of the handles 124. Pressure can also be put on the handles by attaching the leads holder to the voltmeter and then squeezing one handle with the meter in the same hand. The leads holder can be made to attach to the voltmeter so that the leads holder and test instrument can be one unit. An adapter that attaches the leads holder to the voltmeter using bolts, washers and a spacer is shown in the drawings.

In one example, a one handed test leads holder tool is made as follows. The tool is shaped like a pair of wire strippers with two long arms that pivot so that the arms can move the attached test leads wider or closer together. The two test leads click into the one handed test leads holder tool on distal ends of the two arms. One arm can be made to be flexible 104, and or, extent out with a telescopic like tube 110 for more reach. The other arm can remain stationary 106. This leads holder tool can be electrically insulated or coated with non-metallic materials such as carbon fiber or rubber.

This one handed test leads holder tool can also be made with a wire stripper and wire cutting edges between the arms for convenience.

In one example, a leads holder tool is attached to a rubber voltmeter/multi-meter adapter. Then, a voltmeter/multi-meter is attached to the adapter. Next, test leads are attached to the arms of the leads holder. The arms of the tool can be extended or bent to make the easiest or safest contact with test points.

FIG. 2 illustrates a front view showing a tool having removable flexible arms including a short flexible extension arm 128 in accordance with one embodiment. The tool includes an optional longer flexible extension arm 130 and an adapter/holder 132 for a test instrument (e.g., voltmeter/multi-meter).

Bolt holes 134 allow attachment of test leads holder tool to adapter 132.

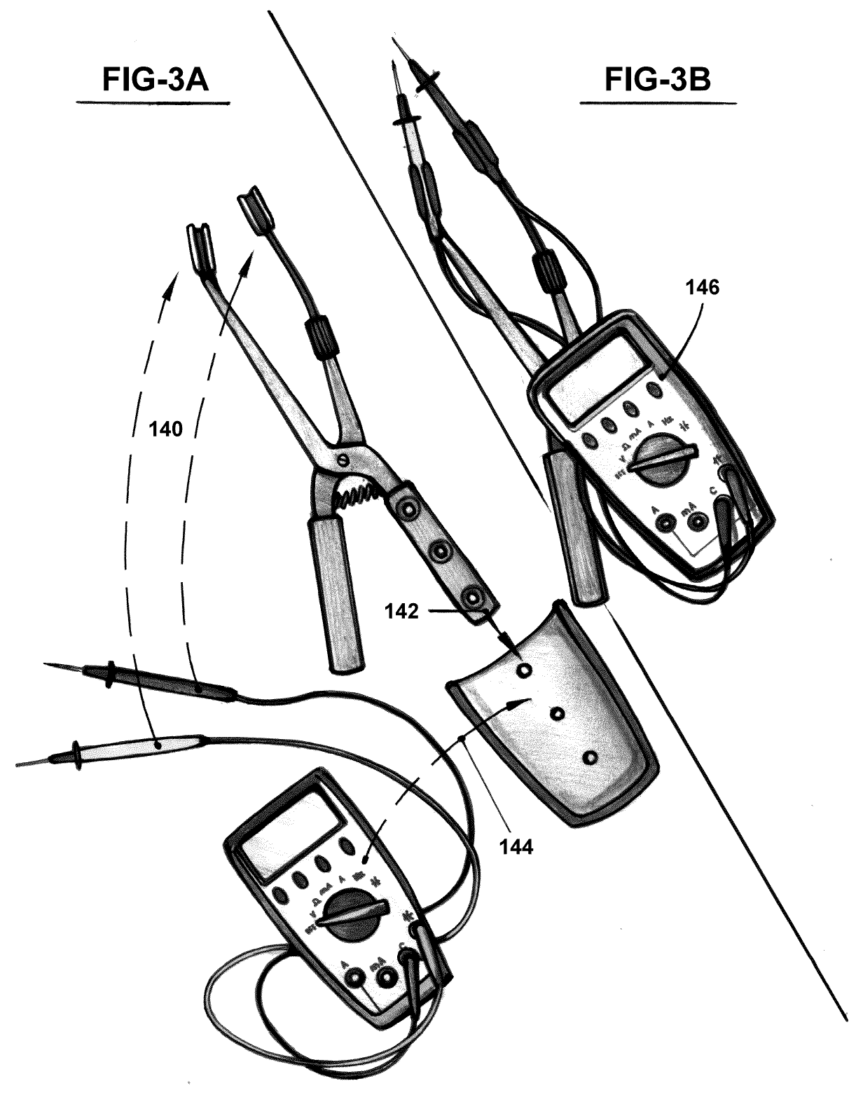

FIGS. 3A and 3B illustrate a method 138 of attaching a test instrument to a test leads holder in accordance with one embodiment. Initially, at operation 140, the method includes attaching the two test leads onto the arms of test leads holder tool 142. At operation 142, the method includes attaching test leads holder tool to a test instrument holder (e.g., voltmeter/multi-meter adapter/holder). At operation 144, the method includes attaching a test instrument (e.g., voltmeter/multi-meter) to adapter/holder. At operation 146, test leads holder tool, test instrument holder, and test instrument (e.g., voltmeter/multi-meter) have been combined into one unit to be held with a single hand of a user.

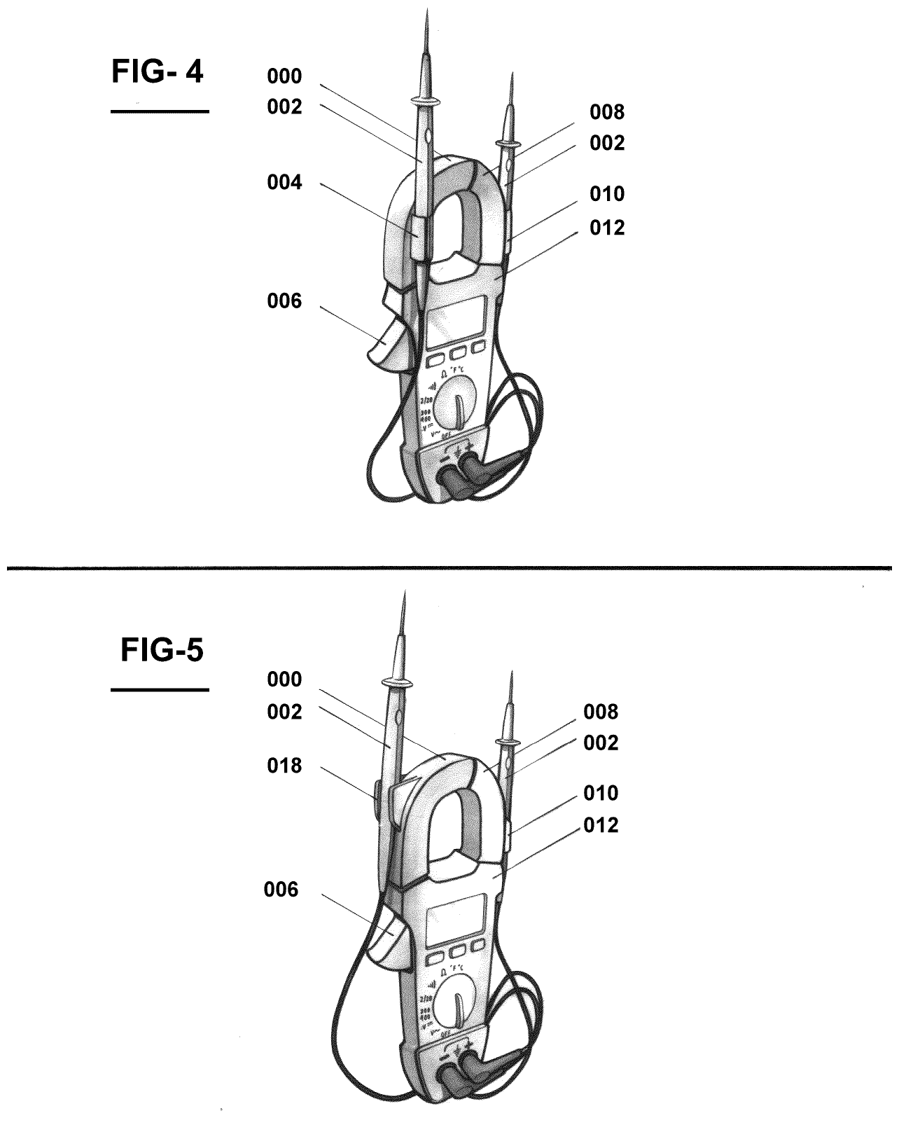

FIG. 4 illustrates the front side of an ammeter having a test leads holder in accordance with one embodiment. Test leads 002 are electrically connected to ports of the ammeter 012. A one handed test lead holder 004, 010 is attached or molded to the opening jaw 000, 008 respectively of the ammeter. The ammeter includes a finger button/trigger 006 for opening or closing the ammeter jaws.

FIG. 5 illustrates the front side of a test instrument (e.g., an ammeter) having a test leads holder with jaws in a closed position in accordance with one embodiment. Test leads 002 are electrically connected to ports of the ammeter 012. A one handed test lead holder 010, 018 is attached or molded to the opening jaws of the ammeter 012. The ammeter includes a finger button/trigger 006 for opening an ammeter jaws. The ammeter 012 is drawn in a jaws closed position.

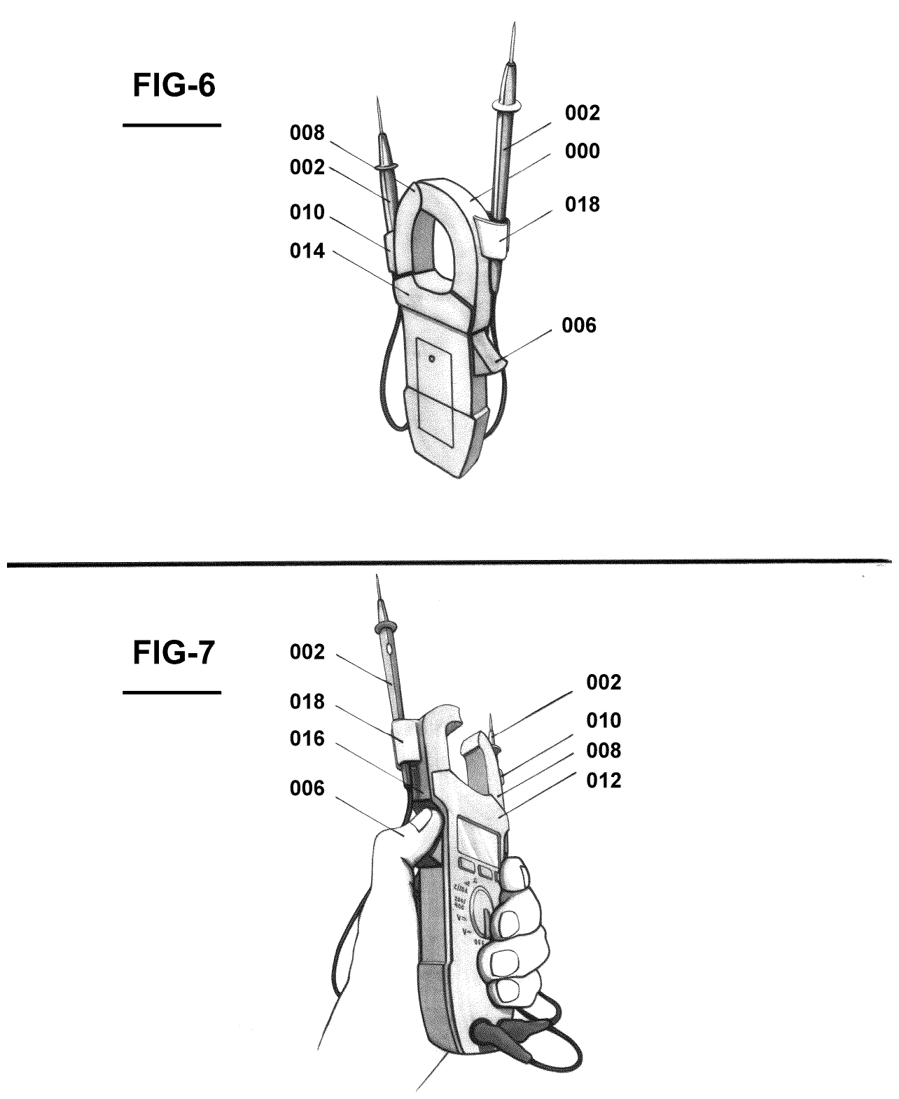

FIG. 6 illustrates the back side of a test instrument (e.g., an ammeter) having a test leads holder with jaws in a closed position in accordance with one embodiment. Test leads 002 are electrically connected to ports of the ammeter 014. A one handed test lead holder 010, 018 is attached or molded to the opening jaws of the ammeter 014. The ammeter includes a finger button/trigger 006 for opening an ammeter jaws.

FIG. 7 illustrates the front side of a test instrument (e.g., an ammeter) having a test leads holder with jaws in an open position in accordance with one embodiment. Test leads 002 are electrically connected to ports of the ammeter 012. A one handed test lead holder 010, 018 is attached or molded to a side of the opening jaws of the ammeter 012. The ammeter includes a finger button/trigger 006 for opening an ammeter jaws.

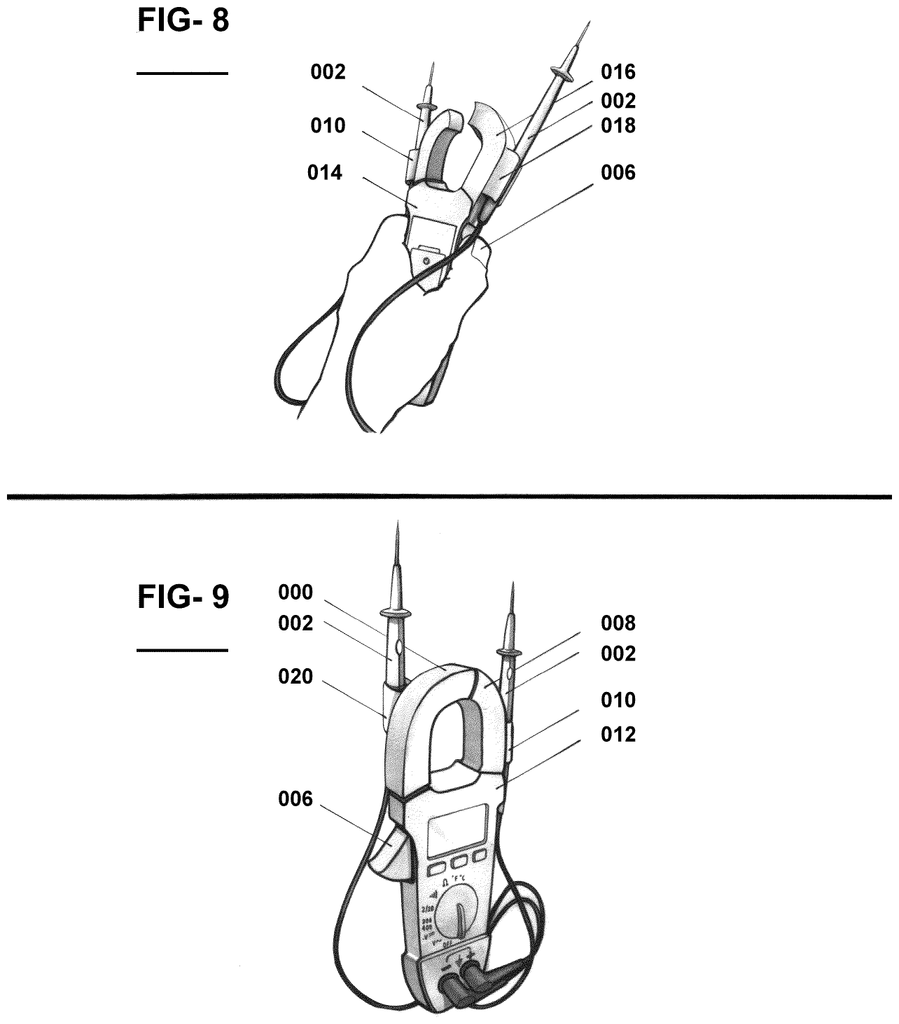

FIG. 8 illustrates the back side of a test instrument (e.g., an ammeter) having a test leads holder with jaws in an open position in accordance with one embodiment. Test leads 002 are electrically connected to ports of the ammeter 014. A one handed test lead holder 010, 018 is attached or molded to a side of the opening jaws of the ammeter 014. The ammeter includes a finger button/trigger 006 for opening an ammeter jaws.

FIG. 9 illustrates the front side of a test instrument (e.g., an ammeter) having a test leads holder with jaws in a closed position in accordance with one embodiment. Test leads 002 are electrically connected to ports of the ammeter 012. A one handed test lead holder 010, 020 is attached or molded to a side or back of the opening jaws of the ammeter 012. The ammeter includes a finger button/trigger 006 for opening an ammeter jaws.

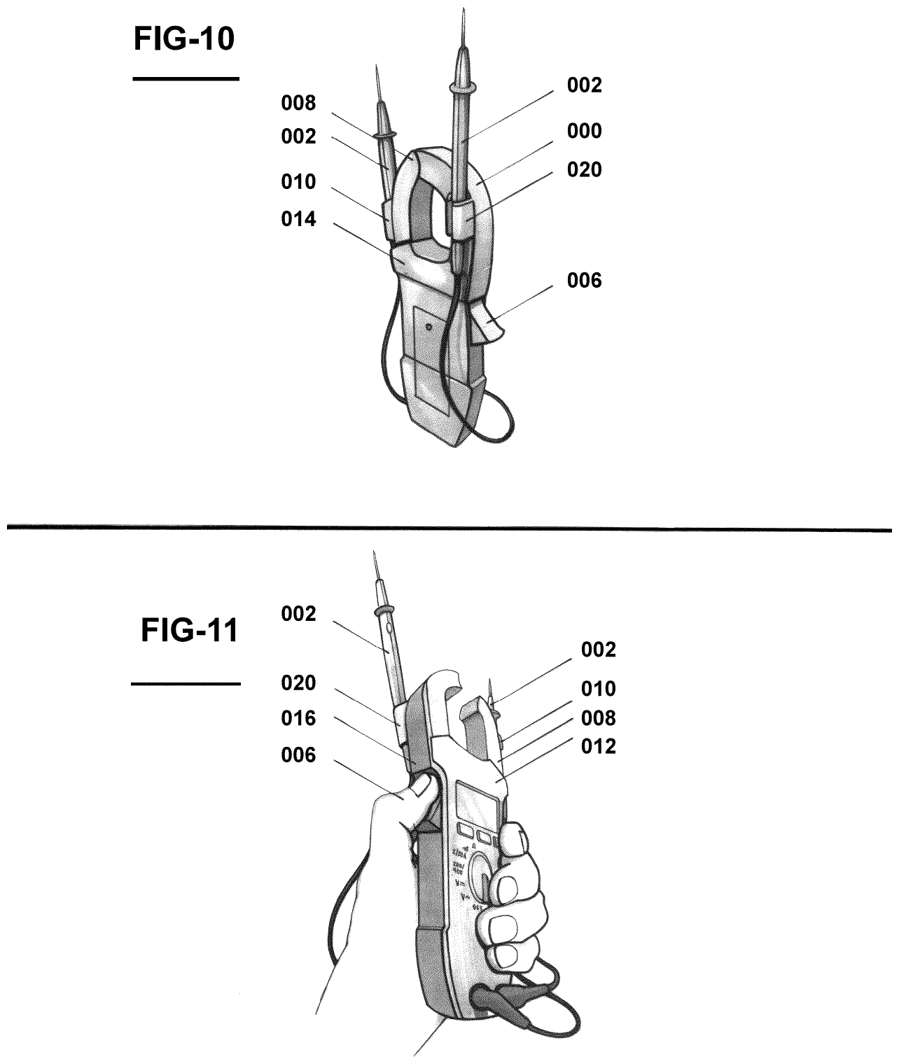

FIG. 10 illustrates the back side of a test instrument (e.g., an ammeter) having a test leads holder with jaws in a closed position in accordance with one embodiment. Test leads 002 are electrically connected to ports of the ammeter 014. A one handed test lead holder 010, 020 is attached or molded to the back of the opening jaws of the ammeter 014. The ammeter includes a finger button/trigger 006 for opening an ammeter jaws.

FIG. 11 illustrates the front side of a test instrument (e.g., an ammeter) having a test leads holder with jaws in an open position in accordance with one embodiment. Test leads 002 are electrically connected to ports of the ammeter 012. A one handed test lead holder 010, 020 is attached or molded to the back of the opening jaws of the ammeter 012. The ammeter includes a finger button/trigger 006 for opening an ammeter jaws.

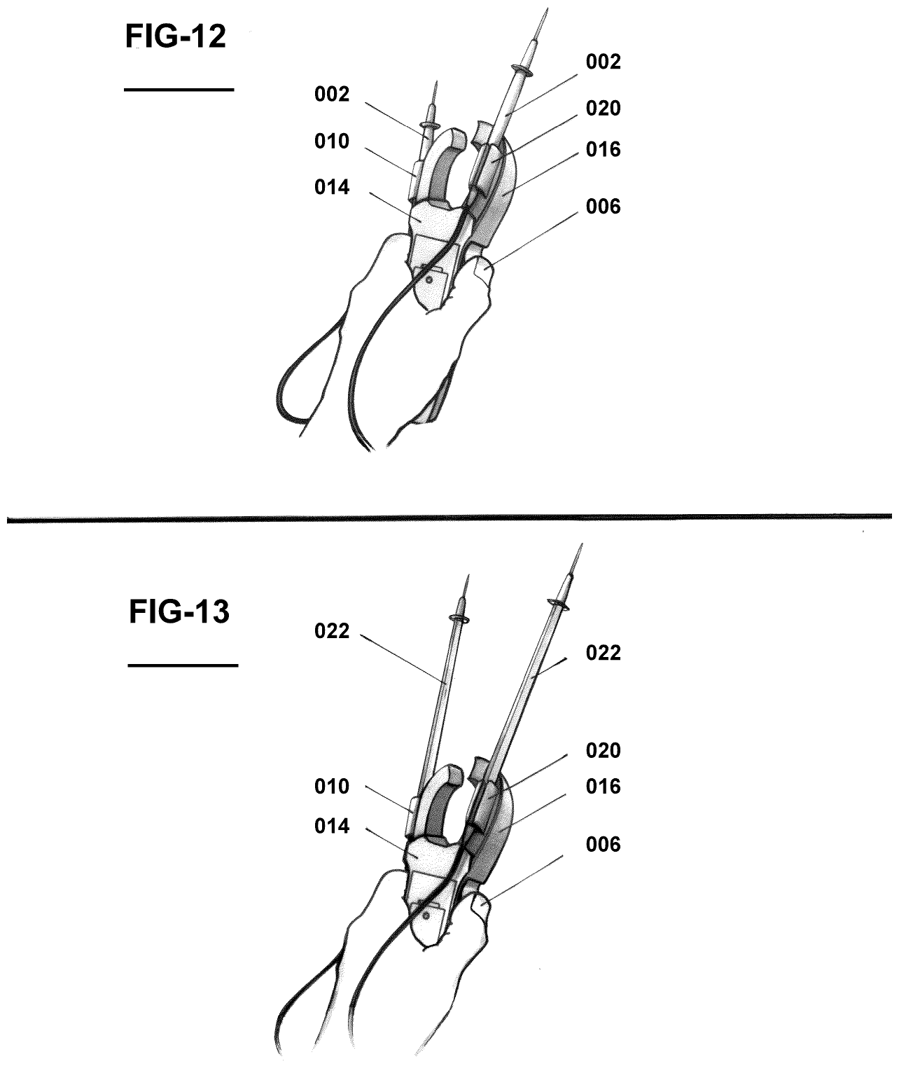

FIG. 12 illustrates the back side of a test instrument (e.g., an ammeter) having a test leads holder with jaws in an open position in accordance with one embodiment. Test leads 002 are electrically connected to ports of the ammeter 014. A one handed test lead holder 010, 020 is attached or molded to the back of the opening jaws of the ammeter 014. The ammeter includes a finger button/trigger 006 for opening an ammeter jaws.

FIG. 13 illustrates a test instrument (e.g., an ammeter) having a test leads holder with jaws in an open position with longer accessory test leads attached in accordance with one embodiment. The longer accessory test leads 022 are electrically connected to the ports of the ammeter 014. A one handed test lead holder 010, 020 is attached or molded on to the back of the opening jaws of the ammeter 014. The ammeter includes a finger button/trigger 006 for opening an ammeter jaws.

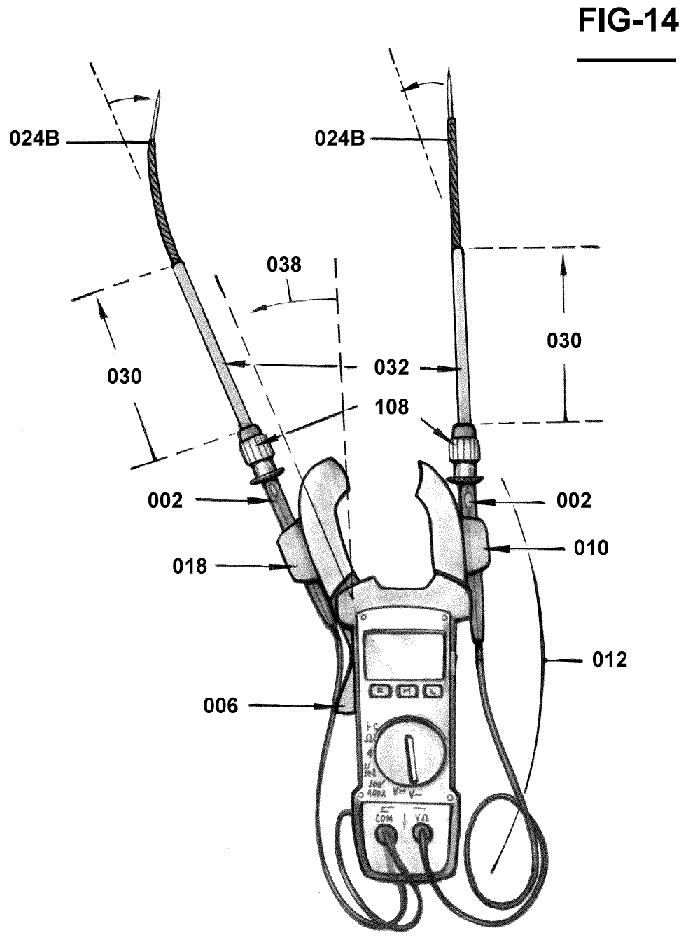

FIG. 14 illustrates a test instrument (e.g., an ammeter) having a test leads holder with jaws in an open position and test leads extensions in accordance with one embodiment. The test leads extensions 032 include flexible/telescoping/extendable arms have an extendable length and are shown as extended 030 to better reach and perform electrical tests. The flexible members 024B are adapted for testing a test point of the electrical device. The jaws of the ammeter have a range of motion 038. The ammeter 012 shown is typical for ammeters with multimeter and voltage meter functions.

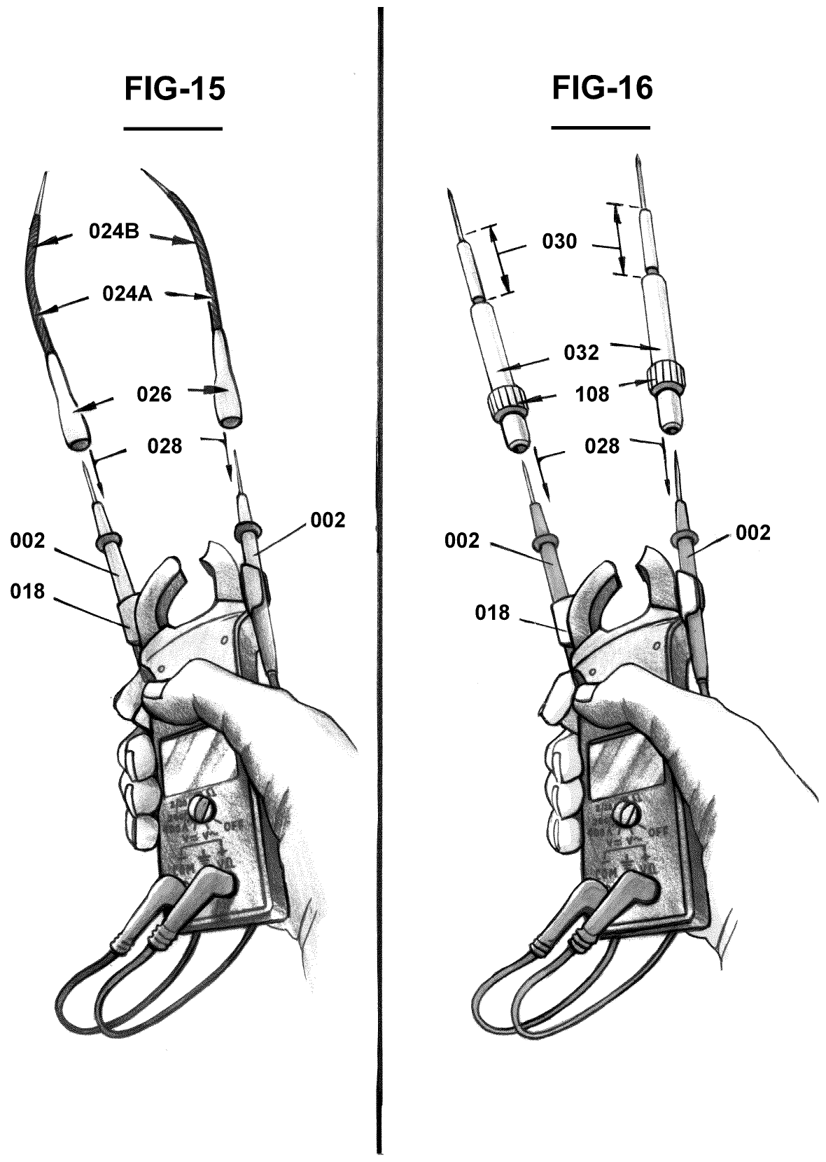

FIG. 15 illustrates a test instrument (e.g., an ammeter) having a test leads holder with jaws in an open position and flexible test leads extensions in accordance with one embodiment. The flexible test leads extensions 026 include flexible members 024 having a flexible range and the test leads can have a non-metallic insulation/coating. The flexible members 024 include a stiff portion 24A with a first end and a flexible portion 024B with a second end. Flexible members 024 of removable test lead extensions 026 attach as shown with arrows 028 to standard test leads 002. The first end of the stiff portion 24A is adapted to attach to a first test lead that is electrically coupled to the one handed testing device and the second end of the flexible portion 024B is adapted for testing a test point of the electrical device.

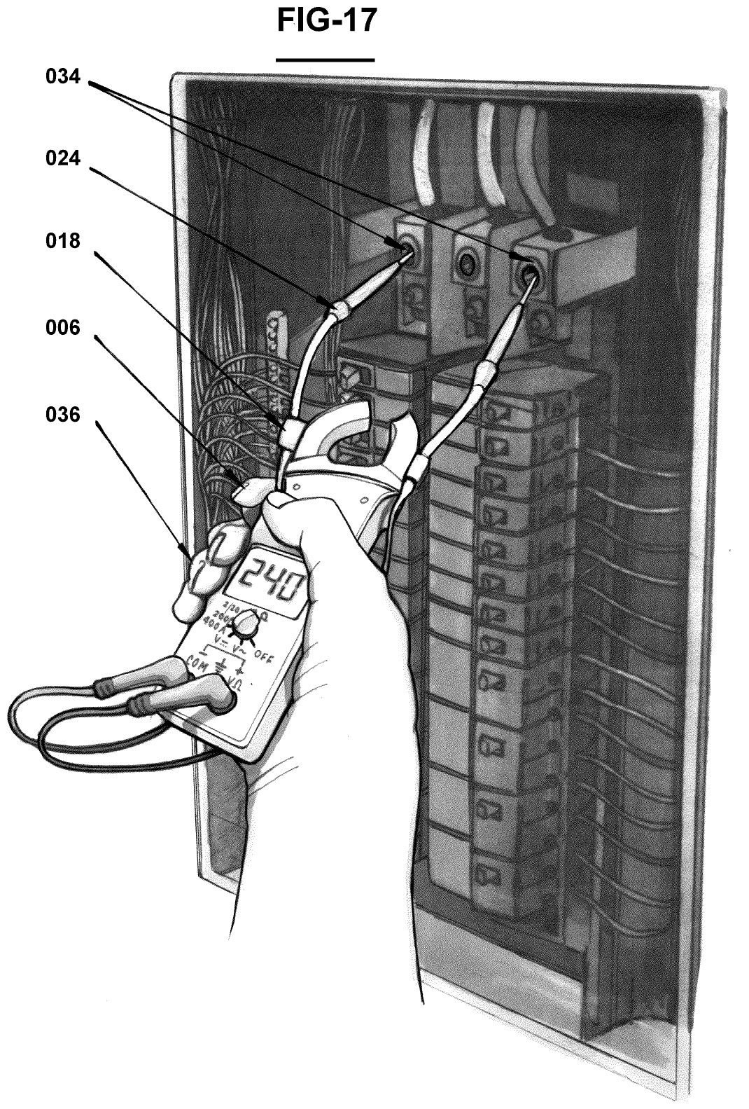

FIG. 16 illustrates a test instrument (e.g., an ammeter) having a test leads holder with jaws in an open position and test leads extensions in accordance with one embodiment. The test leads extensions 032 include telescoping/extendable arms having an extendable length 030. Removable test lead extensions 032 attach as shown with arrows 028 to standard test leads 002. The extendable arm sleeve has a tightening nut 108.

FIG. 17 illustrates a test instrument (e.g., an ammeter) having a test leads holder with jaws in an open position and flexible test leads being connected to electrical lugs in an electrical panel in accordance with one embodiment. The flexible test leads 024 have a flexible range and the test leads can have a non-metallic insulation/coating. A one handed test lead holder 018 is attached or molded to a side of the opening jaws of the ammeter. The ammeter includes a finger button/trigger 006 for opening an ammeter jaws. With one hand the user 036 is shown able to connect/touch a pair of test leads 104 to two different lugs in an electrical panel 034.

In some embodiments, electrical test tools include a one handed test leads holder tool and a test leads holder of a test instrument for one handed testing of an electrical device. According to some embodiments for Example 1, a one handed test leads holder tool, comprises a first elongated member having a first non-metallic clip at a distal end to hold a first test lead, a second elongated member having an extendable or removable segment and a second non-metallic clip at a distal end to hold a second test lead, and a pivot to pivotally couple the first

elongated member to the second elongated member to allow a user to position the first test lead and the second test lead with one hand while holding the first and second elongated members to test electrical parameters of an electrical device without the risk of having electrical current accidentally pass through the body of the user.

Example 2 includes the subject matter of Example 1, the one handed test leads holder tool, further comprises a nut to lock or unlock the extendable or removable segment of the second elongated member.

Example 3 includes the subject matter of any of Examples 1-2, the one handed test leads holder tool, further comprises a biasing mechanism to bias a spacing between the first elongated member and the second elongated member.

Example 4 includes the subject matter of any of Examples 1-3, the one handed test leads holder tool, further comprises adapter holes for attaching the one handed test leads holder tool to an adapter or holder that is designed to hold a test instrument for testing the electrical parameters of the electrical device.

Example 5 includes the subject matter of any of Examples 1-4, the one handed test leads holder tool, wherein a spacing between the first test lead and the second test lead is adjustable by applying pressure to a handle of the first elongated member while the user holds the one handed test leads holder tool, the adapter or holder, and the test instrument with one hand.

Example 6 includes the subject matter of any of Examples 1-5, wherein the first test lead is held by tension of the first clip on the distal end.

Example 7 includes the subject matter of any of Examples 1-6, wherein a spacing between the first test lead and the second test lead is adjustable by applying pressure to a handle of the first elongated member and a handle of the second elongated member.

Some embodiments relate to Example 8 that includes a one handed test apparatus, comprising one handed test leads holder tool having a first elongated member that includes a first non-metallic clip at a distal end to hold a first test lead, a second elongated member having an extendable or removable segment and a second non-metallic clip at a distal end to hold a second test lead, and a pivot to pivotally couple the first elongated member to the second elongated member to allow a user to position the first test lead and the second test lead with one hand while holding the first and second elongated members to test electrical parameters of an electrical device without having electrical current go through a body of the user and an adapter to hold a test instrument and being capable of attachment to the one handed test leads holder tool.

Example 9 includes the subject matter of Example 8, wherein the pivot allows the user to position the first test lead and the second test lead with one hand while holding the first and second elongated members to test electrical parameters of an electrical device without having electrical current accidentally pass through the body of the user.

Example 10 includes the subject matter of any of Examples 8-9, wherein the one handed test leads holder tool includes adapter holes for using adapter bolts, washers and nuts for attaching the one handed test leads holder tool to the adapter.

Example 11 includes the subject matter of any of Examples 8-10, the one handed test apparatus further comprises an adapter spacer to provide a spacing between the adapter and the one handed test leads holder tool.

Example 12 includes the subject matter of any of Examples 8-11, wherein a spacing between the first test lead and the second test lead is adjustable by applying pressure to a handle of the first elongated member while the user holds the one handed test leads holder tool, the adapter, and the test instrument with one hand.

Example 13 includes the subject matter of any of Examples 8-12, wherein a spacing between the first test lead and the second test lead is adjustable by applying pressure to a handle of the first elongated member and a handle of the second elongated member.

Some embodiments relate to Example 14 that includes a test leads holder for attachment to a handheld test instrument, comprising a first test lead holder having an external surface for attachment to a first jaw of the handheld test instrument and an internal surface of the first test leads holder having an opening for inserting a first test lead to hold the first test lead, wherein a user moves the handheld test instrument with one hand to position the first test lead with one hand to test voltages of an electrical device without having electrical current accidentally pass through the body of the user.

Example 15 includes the subject matter of Example 14, the test leads holder further comprises a second test lead holder having an external surface for attachment to a second jaw of the handheld test instrument and an internal surface of the second test leads holder having an opening for inserting a second test lead to hold the second test lead, wherein the user moves the handheld test instrument with one hand to position the first test lead and the second test lead with one hand to test voltages of the electrical device without having electrical current accidentally pass through the body of the user.

Example 16 includes the subject matter of any of Examples 14-15, wherein the opening of the first test lead holder has a diameter to approximately match a diameter of the first test lead.

Example 17 includes the subject matter of any of Examples 14-16, wherein the first test lead holder is formed of plastic.

Example 18 includes the subject matter of any of Examples 14-17, wherein the first test lead holder is attached or molded to a side surface of the first jaw of the handheld test instrument.

Example 19 includes the subject matter of any of Examples 14-18, wherein the first test lead holder is attached or molded to a front surface of the first jaw of the handheld test instrument.

Example 20 includes the subject matter of any of Examples 14-19, wherein the first test lead holder is attached or molded to a back surface of the first jaw of the handheld test instrument.

In the foregoing specification, embodiments have been described with reference to specific exemplary embodiments thereof. It will be evident that various modifications may be made thereto without departing from the broader spirit and scope of the invention as set forth in the following claims. The specification and drawings are, accordingly, to be regarded in an illustrative sense rather than a restrictive sense.

What is claimed is:

1. A test instrument, comprising:
a handheld testing device having pivoting first and second jaws to pivot from a first open position with a spacing between the distal ends of the first and second jaws and a second closed position with no spacing between the distal ends of the first and second jaws;
a first test leads holder attached to the first jaw and having an opening to hold a first test lead;
a second test leads holder attached to the second jaw and having an opening to hold a second test lead; and
a pivot to pivotally couple the first jaws and the second jaws to allow a user to adjust a spacing between the first test lead and the second test lead with one hand to test voltage of an electrical device without having electrical current accidentally go through a body of the user.

2. The test instrument of claim 1, further comprising:
a pressable selector or button to allow the user to pivot the first and second jaws from a first open position with a spacing between the distal ends of the first and second jaws to a second closed position with no spacing between the distal ends of the first and second jaws.

3. The test instrument of claim 1, wherein the pressable selector or button allows the user to pivot the first and second jaws from the second closed position with no spacing between the distal ends of the first and second jaws to the first open position with spacing between the distal ends of the first and second jaws.

4. The test instrument of claim 1, wherein the pressable selector enables the user to adjust a spacing between the first test lead and the second test lead with one hand to test voltage of an electrical device without having electrical current accidentally go through the body of the user.

5. The test instrument of claim 1, wherein the first and second test leads are flexible each having a range of movement for testing the electrical device.

6. The test instrument of claim 1, further comprising:
a first test lead extension to attach to an end of the first test lead to provide additional reach in contacting active test points of the electrical device.

7. The test instrument of claim 1, further comprising:
a second test lead extension to attach to an end of the second test lead to provide additional reach in contacting active test points of the electrical device.

8. The test instrument of claim 1, further comprising:
a first flexible test lead extension to attach to an end of the first test lead to provide additional reach in contacting active test points of the electrical device.

9. The test instrument of claim 1, further comprising:
a gripping surface on a backside of the test instrument to allow the user to grip and operate the test instrument with one hand.

10. The test instrument of claim 1, further comprising:
a first extendable test lead extension to attach to an end of the first test lead to provide customizable adjustable extension for additional reach in contacting active test points of the electrical device.

11. The test instrument of claim 1, further comprising:
a second extendable test lead extension to attach to an end of the second test lead to provide customizable adjustable extension for additional reach in contacting active test points of the electrical device.

12. A test lead extension for a one handed test instrument for testing an electrical device comprising:
an elongated member having a stiff portion with a first end and a flexible portion with a second end;
the first end is adapted to attach to a first test lead that is electrically coupled to the one handed testing instrument; and
the second end is adapted for testing a test point of the electrical device, wherein the flexible portion including the second end has a range of movement to allow a user to adjust a spacing between the test lead extension and an additional test lead extension for testing electrical parameters of the electrical device with the one handed test instrument.

13. The test lead extension of claim 12, wherein the first end includes an opening for attaching to the first test lead.

14. The test lead extension of claim 12, wherein the elongated member provides reach in addition to the reach of the first test lead for testing the test point of the electrical device.

15. The test lead extension of claim 12, wherein the flexible portion is capable of being positioned in an outwards position away from the additional test lead extension for a first spacing, in a neutral position aligned with the stiff portion for a second spacing with respect to the additional test lead extension, and in an inwards position towards the additional test lead extension for a third spacing with respect to the additional test lead extension.

16. A test lead extension for a one handed test instrument for testing an electrical device comprising:
a elongated member having a first portion with a first end and a second extendable portion with a second end;
the first end is adapted to attach to a first test lead that is electrically coupled to the one handed testing device; and
the second end is adapted for testing a test point of the electrical device, wherein the second extendable portion including the second end has an adjustable length to allow a user to adjust a reach of the test lead extension for testing electrical parameters of the electrical device with the one handed test instrument.

17. The test lead extension of claim 16, wherein the first end includes an opening for attaching to the first test lead.

18. The test lead extension of claim 16, wherein the elongated member provides reach in addition to the reach of the first test lead for testing the test point of the electrical device.

19. The test lead extension of claim 16, wherein the extendable second portion is capable of being adjusted between having a first length and a second length.
